(19) United States
(12) Patent Application Publication
(10) Pub. No.: US 2005/0061245 A1
(43) Pub. Date: Mar. 24, 2005

(54) Chemical vapor deposition apparatus

(76) Inventor: Jeong-Yun Kim, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/937,445

(22) Filed: Sep. 10, 2004

(30) Foreign Application Priority Data
Sep. 15, 2003 (KR) 2003-63514

(51) Int. Cl. C23C 16/00

(52) U.S. Cl. 118/715

(57) ABSTRACT

A chemical vapor deposition apparatus includes a source gas box, a process chamber, a vacuum pump, a discharge pipe pressure sensor, a dump line and a pressure sensor protecting valve. The source gas box produces source gas by bubbling an inactive gas through a source solution. A metal thin film is formed on a wafer in the chamber under predetermined temperature and pressure using the source gas. The vacuum pump discharges residual gas from the chamber through discharge piping extending from the chamber. The discharge pipe pressure sensor senses the pressure within the discharge piping. The dump line bypasses the process chamber. The pressure sensor protecting valve prevents source gas and the like from flowing to the discharge pipe pressure sensor when the source gas is discharged through the dump line during a dummy flow operation.

### BACKGROUND OF THE INVENTION

1. Field of the Invention

The present invention relates to a chemical vapor deposition apparatus.

2. Description of the Related Art

Semiconductor manufacturing industries are continually trying to reduce the line width of integrated circuits in order to produce semiconductor chips that will operate at higher speeds and store a great amounts of an information per unit area. As a result of these efforts, active and passive devices, for example, transistors, have critical dimensions that are now on the order of less than half a micron.

Moreover, semiconductor chips now typically include a three-dimensional structure, such as a capacitor formed on a bit line, in order to provide the chip with a high degree of integration. This part of the device, namely the contact hole in which the capacitor is formed, has a high aspect ratio. Thus, the semiconductor fabricating process must produce good step coverage with respect to the contact hole.

However, it is difficult to satisfactorily fill a contact hole with conductive material (also referred to as burying) using a conventional physical vapor deposition (PVD) process. More specifically, PVD is a process in which a metal layer is formed by evaporating (or sputtering) metal from a target and condensing the metal vapor on the surface of a wafer. When the aspect ratio of the contact hole is great, a geometrical shadow effect makes it difficult to bury the contact hole, i.e., to provide a satisfactory step coverage. That is, the PVD process is carried out under a high vacuum wherein the atoms of the deposition metal have a large mean free path and coefficient of adhesion. Thus, only a region of the contact hole within a line of sight of the target is coated with metal and hence, the deposition of the metal does not satisfactorily conform to the surface defining the contact hole.

In order to solve this problem, chemical vapor deposition (CVD) is being actively practiced as a means of providing a short mean free path for the atoms of the source gas and of producing atoms having a low coefficient of adhesion. In comparison with PVD, the atoms of the source gas in chemical vapor deposition reach the surface of wafer after undergoing many more collisions, and the deposition occurs through a diffusion of the metal into the surface. Thus, CVD can produce a metal layer that conforms to the surface on which it is formed better than a metal layer produced using PVD.

In a metal wiring process carried out using CVD, tungsten has been used to fill and bury a contact hole having a high aspect ratio. However, tungsten is disadvantageous in terms of its resistance, and in that a tungsten layer formed by CVD must be subsequently planarized by an etch back or chemical mechanical polishing (CMP) process. Therefore, a chemical vapor deposition apparatus that can form a layer of aluminum is now being used in the fabricating of semiconductor devices.

Such a prior art chemical vapor deposition apparatus will be described with reference to FIG. 1.

The conventional chemical vapor deposition apparatus includes a source gas box 10, a chamber 30, a first pressure sensor 40, an auxiliary gas box 50, a first vacuum pump 70, an automatic pressure control valve 81, a roughing valve 80, a second vacuum pump 71, a gate valve 82, a fore line valve 83, a dump line 90, a dump valve 91 and a second pressure sensor 41.

The source gas box 10 bubbles a source solution using an inactive gas to generate source gas. Also, the source gas box 10 controls the pressure and density of the source gas so that the source gas has uniform flow characteristics. A metal thin film is formed on a wafer under a predetermined temperature and pressure in the chamber 30 using the source gas supplied from the source gas box 10 through a source gas supply pipe 20. The first pressure sensor 40 senses the pressure in the chamber 30. The auxiliary gas box 50 supplies the inactive gas to the interior of the chamber 30 so as to prevent the source gas from reacting with the interior of the chamber 30 in the forming of the thin film. The first vacuum pump 70 produces a predetermined vacuum pressure to pump residual gas within the chamber 30 through first and second discharge pipes 60, 61 that are connected through the chamber 30.

Also, the automatic pressure control valve 81 is installed on the first discharge pipe 60 and controls the pressure within the chamber 30. The roughing valve 80 serves to protect the automatic pressure control valve 81 when the pressure in the chamber 30 is lower than the pressure produced by the first vacuum pump 70. The second vacuum pump 71 discharges the residual gas flowing into a dummy discharge pipe 62 that diverges from the first discharge pipe 60. The gate valve 82 cuts off the residual gas from the automatic pressure control valve 81 during the operation of the second vacuum pump 71.

Furthermore, the fore line valve 83 prevents the residual gas from flowing through the dummy discharge pipe 62 when the residual gas is being discharged via the automatic pressure control valve 81. The dump line 90 extends between the source gas supply pipe 20 and the second discharge pipe 61, and discharges source oxide supplied from the source gas box 10 through the source gas supply pipe 20. The dump valve 91 is installed on the dump line 90 and is opened during a dummy flow operation. The second pressure sensor 41 senses the pressure created by the first vacuum pump 70 within the first and second discharge pipes 60, 61.

The conventional chemical vapor deposition apparatus as described above controls the flow of the source gas, and controls the operation of the first vacuum pump 70 so that the pressure produced thereby is lower than that of the pressure within the chamber 30. Also, the apparatus uses the automatic pressure control valve 81 to control the amount of the residual gas discharged by the first vacuum pump 70, to thereby maintain a uniform pressure within the chamber 30. Accordingly, the process of forming a metal thin film on the surface of the wafer has good reproducibility.

Also, in the conventional chemical vapor deposition apparatus, the source gas box 10 includes a hot box 14 for heating the inactive gas to a predetermined temperature, a transport gas supply pipe 11, a diluted gas supply pipe 12 and a hot gas supply pipe 13 for supplying the inactive gas, a diluted gas, and a heated gas to the hot box 14 from outside the source gas box, and a source ampoule 15 for bubbling the source solution using the inactive gas heated in the hot box 14 to thereby generate heated source gas. The source gas box 10 further includes a sealed chamber 16 surrounding the hot box 14 and the source ampoule 15. The sealed chamber receives hot gas supplied through the hot gas supply pipe 13 and discharges the gas to a scrubber 17.

About ⅔ of the source ampoule 15 is filled with the source solution, and is compressed by nitrogen gas at a high pressure. The source ampoule 15 should be periodically replaced, e.g., after a certain number of thin films have been formed on a wafer using the apparatus.

A dummy flow operation is performed once the source ampoule 15 is replaced. The dummy flow operation causes nitrogen gas and an oxide on the surface of the source solution to bypass the chamber 30 through the dump line 90. That is, the dump valve 91 is opened so that the nitrogen gas and source oxide in a new unused source ampoule 15 are discharged by the first vacuum pump 70 through the dump line 90 via the source gas supply pipe 20. Therefore, the source gas and source oxide will not pollute the interior of the chamber 30 where the deposition process takes place.

However, the conventional chemical vapor deposition apparatus has the following problems.

During the dummy flow operation, the source gas or the source oxide flows into the second pressure sensor 41 disposed along the second discharge pipe 61. As a result, metallic material is deposited in the second pressure sensor 41, thereby making the second pressure sensor 41 inoperable. This, in turn, not only shortens the useful life of the second pressure sensor but also causes defects to occur in a subsequent deposition process. Accordingly, the productivity of the process is reduced, and maintenance or replacement of the pressure sensor gives rise to increased manufacturing costs.

### SUMMARY OF THE INVENTION

Accordingly, an object of the present invention is to provide a chemical vapor deposition apparatus in which a pressure sensor for sensing the pressure in the discharge piping is protected during a dummy flow operation.

According to one aspect of the invention, a chemical vapor deposition apparatus includes a source gas box, a source gas supply pipe, a chamber, discharge piping, a first vacuum pump, a pressure sensor, a dump line and a pressure sensor protecting valve. The source gas box produces source gas by bubbling an inactive gas through source solution. A metal thin film is formed on a wafer under a predetermined temperature and pressure in the chamber using source gas supplied to the chamber through the source gas supply pipe. The vacuum pump discharges residual gas from the chamber through the discharge piping, and the pressure sensor is connected to the discharge piping to sense the pressure within the discharge piping during the thin film forming process. The dump line extends between the source gas supply pipe and the second discharge pipe, and bypasses the chamber.

On the other hand, source gas and source oxide or the like are discharged by the vacuum pump through the dump line and discharge piping during a dummy flow operation. The pressure sensor protecting valve cuts off the second pressure sensor from the source gas and source oxide flowing through the dump line and the discharge pipe during the dummy flow operation.

According to another aspect of the invention, the chemical vapor deposition apparatus also includes a first pressure sensor, and an auxiliary gas box connected to the process chamber. The first pressure sensor thus senses the pressure within the process chamber during the thin film forming operation. The auxiliary gas box includes at least one auxiliary gas pipe extending to the process chamber for feeding inactive gas to the process chamber during the thin film forming apparatus.

In addition, the discharge piping may include a first discharge pipe, a second discharge pipe disposed in series with the first discharge pipe, and a dummy discharge pipe disposed in parallel with the first discharge pipe. The first vacuum pump is connected to the second discharge pipe. A second vacuum pump and a fore line valve are disposed along the dummy discharge pipe. A roughing valve, an automatic pressure control valve, and a gate valve are disposed along the first discharge pipe. The dump line and the pressure sensor for sensing the pressure in the discharge piping are connected to the second discharge pipe.

### BRIEF DESCRIPTION OF THE DRAWINGS

The present invention will become more fully understood from the following detailed description of the preferred embodiments thereof made with reference to the accompanying drawings, wherein:

FIG. 1 is a schematic diagram of a chemical vapor deposition apparatus according to the prior art; and

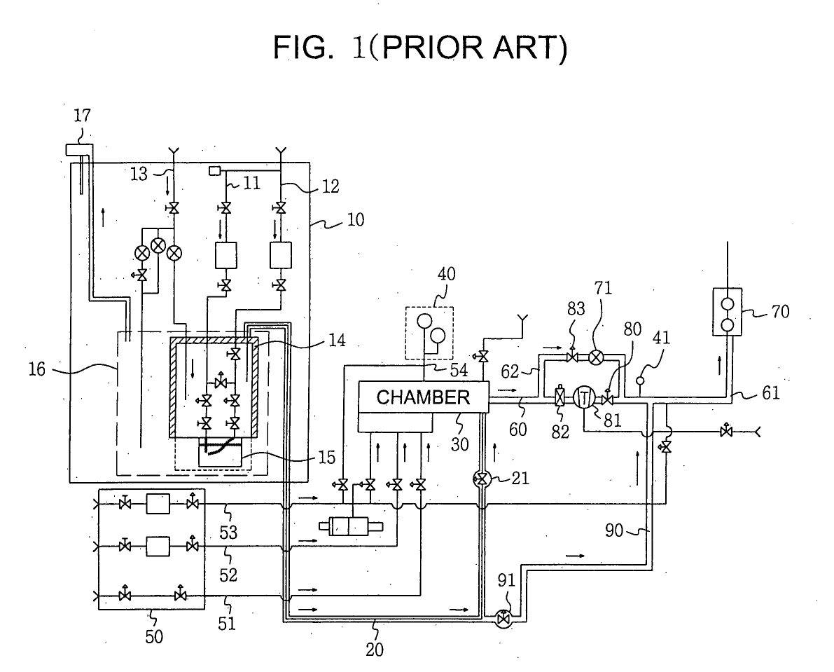

FIG. 2 is a schematic diagram of a chemical vapor deposition apparatus according to the present invention.

### DETAILED DESCRIPTION OF THE PREFERRED EMBODIMENTS

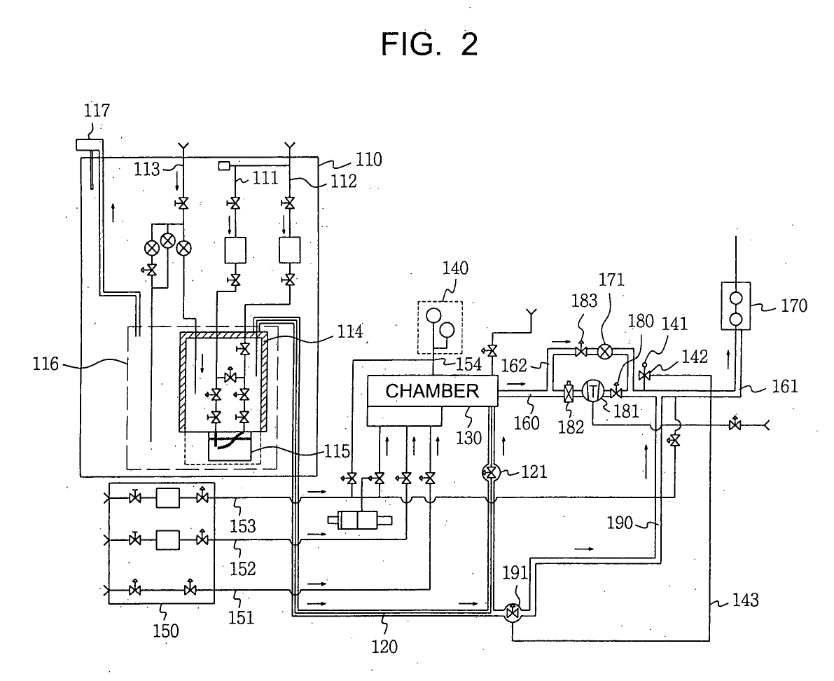

The present invention will now be described in detail with reference to FIG. 2.

A chemical vapor deposition apparatus of the present invention includes a source gas box 110, a chamber 130, a first pressure sensor 140, an auxiliary gas box 150, a first vacuum pump 170, an automatic pressure control valve 181, a roughing valve 180, a second vacuum pump 171, a gate valve 182, a fore line valve 183, a dump line 190, a dump valve 191, a second pressure sensor 41 and a pressure sensor protecting valve 142.

The source gas box 110 produces source gas by bubbling source solution using inactive gas. The source gas is supplied from the source gas box 110 to the chamber 130 through a source gas supply pipe 120. A metal thin film is formed on a wafer under a predetermined temperature and pressure in the chamber 130 using the source gas supplied from the source gas supply pipe 120. The first pressure sensor 140 senses the pressure within the chamber 130.

On the other hand, the auxiliary gas box 150 supplies inactive gas to the chamber 130 so as to prevent the source gas from reacting with the interior of the chamber 130 during the forming of the metal thin film. The inactive gas contains at least one of argon, helium, nitrogen and hydrogen.

The first vacuum pump 170 produces a vacuum pressure that acts to pump residual gas from the chamber 130 through first and second discharge pipes 160, 161 that are connected to the chamber 130. The automatic pressure control valve 181 is disposed along the first discharge pipe 160 and controls the pressure within the chamber 130. The roughing valve 180 cuts off the flow of residual gas from the chamber 130 to protect the automatic pressure control valve 181 when the pressure within the chamber 130 is lower than the pressure produced by the first vacuum pump 170.

The second vacuum pump 171 is preferably a turbo pump and pumps the residual gas through a dummy discharge pipe 162 that branches from and is disposed parallel to the first discharge pipe 160. The gate valve 182 cuts off the flow of the residual gas to the automatic pressure control valve 181 during the operation of the second vacuum pump 171. On the other hand, the fore line valve 183 cuts off the flow of the residual gas through the dummy discharge pipe 162 when the residual gas is being discharged through the first discharge pipe 160 via the automatic pressure control valve 181.

The dump line 190 extends between the source gas supply pipe 120 and the second discharge pipe 161. The dump valve 191 is disposed along the dump line 190 and is opened when a dummy flow operation is performed. In the dummy flow operation is performed, as will be described in more detail later on, source oxide is discharged from the source gas box 110 through the source gas supply pipe 120 while bypassing the chamber 130.

The second pressure sensor 141 senses the pressure that is produced within the first and second discharge pipes 160, 161 by the first vacuum pump 170. The pressure sensor protecting valve 142 is installed between the second pressure sensor 141 and the dump line 190. The pressure sensor protecting valve 142 prevents an influx of source gas and source oxide to the second pressure sensor 141. Accordingly, all of the source gas and source oxide is discharged through the dump line 190 and the second discharge pipe 161 during the dummy flow operation.

Still further, the source gas box 110 includes a hot box 114 having a heating jacket for heating inactive gas to a predetermined temperature, e.g., about 50° C., and a source ampoule 115 containing the source gas under pressure. The inactive gas is supplied to the hot box 114 from outside the source gas box 110 through a transport gas supply pipe 111 and a diluted gas supply pipe 112. The inactive gas heated by the hot box 114 is bubbled through the source solution in the source ampoule 115 to thereby generate source gas.

The source gas box 110 further includes a sealed chamber 116 surrounding the hot box 114 and the source ampoule 115. The sealed chamber receives hot gas supplied through a hot gas supply pipe 113 and discharges the gas to a scrubber 117 so as to maintain the source ampoule 115 at a uniform temperature of about 40° C. to 50° C., for example.

More specifically, inactive gas uniformly flows into the source ampoule 115 from the transport gas supply pipe 111 at a uniform flow rate of, for example, about 500 sccm, in order to bubble the source solution contained in the source ampoule 115. The source gas generated by the bubbling of the source solution is diluted with the inactive gas flowing through the diluted gas supply pipe 112, so as to attain a given density. And then, the source gas is supplied to the chamber 130 through the source gas supply pipe 120.

Preferably, the source solution is 1-methyl pyrrolidine alane (MPA) and fills about ⅔ of the source ampoule 115. The source solution is compressed in the source ampoule 115 by nitrogen gas under high pressure. The source solution has the following characteristic shown in Table 1.

TABLE 1

| Properties | MFA | Molecular Structure. |
|---|---|---|
| Chemical Name | 1-Methylpyrrolidine: alane | 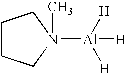 |
| Molecular Wt.(g/mol) | 115.16 | |
| Melting Point(° C.) | ˜15 | |
| Boiling Point(° C.) | ˜55 in vacuum | |
| Vapor Pressure(Torr) | 2 torr @60° C. | |
| Deposition Tenperature | ˜160 | |
| (° C.) | | |
| Viscosity | <10 | |
| Phyrophoricity | Less | |
| Shelf Life | >6 months at room temp | |

The source gas supply pipe 120 is a metal pipe provided with a heating jacket for maintaining the source gas at a predetermined temperature of about 45° C. through 60° C., for example, so as to prevent the source gas from condensing. And, although not shown in the drawing, the chamber 130 further includes a spray nozzle for spraying the source gas onto the wafer, a chuck for supporting the wafer, and a heater for heating the source gas to a predetermined deposition temperature of about 100° C. to about 160° C., for example.

When a metal thin film of, for example, aluminum, is formed on the wafer using the source gas, the chuck is raised from a lower part of the chamber 130 with the wafer fixed at a central portion thereof. At this time, the source gas could potentially react with the chuck or parts adjacent the chuck at the outer periphery of the wafer, and thereby produce metallic material in the chamber. To prevent this problem, inactive gas is supplied from a first auxiliary gas supply pipe 151 of the auxiliary gas box 150 at a uniform flow rate of about 500 sccm, for example, so that the source gas will not settle on the chuck or its surroundings.

Also, the inactive gas flows is fed to the chuck at a uniform rate of, for example, about 300 sccm from a second auxiliary gas supply pipe 152 that is connected to the center of the chuck. At this time, i.e., during the forming of the metal thin film on the wafer, the pressure of the inactive gas supplied to the chuck through the second auxiliary gas supply pipe 152 is lower than the pressure within the chamber 130. Hence, the wafer is fixed to the chuck under a predetermined pressure.

Furthermore, the first pressure sensor 140 comprises a 1 Torr baratron sensor and a 100 Torr baratron sensor installed on a transmission pipe 154 as spaced from the interior of the chamber 130. The first pressure sensor 140 can be protected by cutting off the source gas flowing into the transmission pipe 154 using the inactive gas supplied through a third auxiliary gas supply pipe 153. To this end, the third auxiliary gas supply pipe 153 is connected to the transmission pipe 154 upstream of the first pressure sensor 140. The third auxiliary gas supply pipe 153 is also connected to the second discharge pipe 161. Thus, inactive gas can be supplied to the chamber 130 and to the second discharge pipe 161 to purge them.

During operation, the pressure in the chamber 130 becomes low as the gas therein is discharged through the first and second discharge pipes 160, 161 by the operation of the first vacuum pump 170. The chamber 130 constitutes a portion of a cluster system. The cluster system also comprises a transfer chamber (not shown) connected to the chamber 130 for loading and unloading wafers into and from the chamber 130. The internal pressure of the chamber 130 is maintained at about 1 Torr to 5 Torr during the thin film forming process, whereas the internal pressure of the transfer chamber is maintained at about 1×10⁻⁴ Torr to 1×10⁻⁸ Torr.

The gate valve 182 is closed when the thin film forming process is completed so that the interior of the chamber 130 assumes a high vacuum state. At this time, the residual gas in the chamber 130 is pumped therefrom using the second vacuum pump 171 connected to the dummy discharge pipe 162 that is disposed upstream of the first vacuum pump 170.

On the other hand, during a thin film forming process, the residual gas is discharged using the first vacuum pump 170 only when the pressure in the first and second discharge pipes 160, 161 is lower than the pressure in the chamber 130. Thus, the second pressure sensor 141 disposed along the second discharge pipe 161 measures the vacuum pressure produced by the first vacuum pump 170, the second discharge pipe 161 extending between the first vacuum pump 170 and the first discharge pipe 160. To this end, the second pressure sensor 141 comprises a thermo-couple gauge. A thermo-couple gauge comprises a heated filament, and a thermo-couple in the form of two metal lines joined with the filament. The filament is heated to a predetermined temperature by supplying a uniform electrical current thereto. Also, a voltage is impressed across the thermo-couple. Therefore, when the thermo-couple gage is in a vacuum, gas molecules collide with the filament whereby the filament loses heat. The output voltage of the thermo-couple corresponds to the temperature change of the filament and, based on this temperature change, the gauge determines a mean value of the gas molecules colliding with the filament per unit area. Thus, the pressure is measured by the thermocouple gauge through an indirect method.

Also, during thin film forming processes, the pressure within the chamber 130 is maintained uniform by the automatic pressure control valve 181 so that the process can be performed with good reproducibility. In the meantime, the source ampoule 115 must be periodically replaced. At this time, a dummy flow operation is performed to discharge source oxide from the new source ampoule 115 so that the chamber 130 is not polluted. To this end, a source gas supply valve 121 disposed at the outlet of the source gas supply line 120 is closed, the dump valve 191 disposed at the inlet of the dunp line 190 is opened, the roughing valve 180 disposed on the first discharge pipe 160 is closed, the fore line valve 183 disposed on the dummy discharge pipe 162 is closed, and the first vacuum pump 170 is operated. Thus, source gas, the nitrogen gas and the source oxide are discharged through the dump line 190 and second discharge pipe 161 while bypassing the chamber 130.

Furthermore, in the chemical vapor deposition apparatus according to the present invention, the pressure sensor protecting valve 142 is disposed at an upstream end of the second pressure sensor 141. The pressure sensor protecting valve 142 is closed when the dump valve 191 is opened during the dummy flow operation. Thus, the source gas and source oxide flowing into the dump line 190 and second discharge pipe 161 will not flow to the second pressure sensor 141. Thus, the pressure sensor protecting valve 142 protects the second pressure sensor 141 during the dummy flow operation. On the other hand, the pressure sensor protecting valve 142 is opened when the dump valve 191 is closed because, in this case, the source gas and oxide do not flow into the dump line 190 and the second discharge pipe. The dump valve 191 and the pressure sensor protecting valve 142 may be operated mutually by air pressure supplied through a single pneumatic pressure line 143.

As described above, according to the present invention, during a dummy flow operation, a pressure sensor protecting valve cuts off the flow of source gas or source oxide to a pressure sensor for sensing the pressure in a discharge pipe. Accordingly, the second pressure sensor is prevented from operating erroneously and process defects as a result of a malfunction of the second pressure sensor are likewise prevented. In addition, the useful life of the second pressure sensor is extended.

Finally, although the present invention has been described in detail above with respect to the preferred embodiments thereof, modifications of and changes to the preferred embodiments of the present invention will be apparent to those skilled in the art that. Accordingly, these and other changes and modifications are seen to be within the true spirit and scope of the invention as defined by the appended claims.

1. A chemical vapor deposition apparatus, comprising:
a source of source gas for the deposition process;
a process chamber in which a metal thin film is formed on a wafer;
a source gas supply pipe connecting said source of source gas to said process chamber and through which the source gas is supplied into the chamber;
discharge piping extending from the chamber;
a vacuum pump connected to the discharge piping to produce a vacuum that discharges residual gas within the chamber through the discharge piping;
a discharge pipe pressure sensor connected to the discharge piping so as to sense the pressure within the discharge piping;
a dump line extending between and connected to the source gas supply pipe and the discharge piping, and bypassing the process chamber;
a dump valve disposed along the dump line, and movable between positions at which the dump line is open and closed to the source gas supply pipe, respectively; and
a pressure sensor protecting valve interposed between said discharge piping and said pressure sensor, said pressure sensor protecting valve movable between an open position at which fluid flowing through the discharge piping flows into the pressure sensor and a closed position at which fluid flowing through the discharge piping is prevented from flowing to said pressure sensor.

2. The apparatus of claim 1, wherein said source of source gas comprises a container of source solution, a source of inactive gas, and an inactive gas supply line extending to said container of source solution for connecting a source of inactive gas to the container so that inactive gas is fed into the container to bubble the source solution.

3. The apparatus of claim 1, wherein said source of source gas comprises:
a source ampoule containing source solution,
a hot box,
a transport gas supply pipe and a diluted gas supply pipe extending through said hot box to said ampoule for connecting a source of inactive gas to said ampoule so that heated inactive gas is fed into the source ampoule to bubble the source solution and dilute the same,
a sealed container that surrounds the hot box and the source ampoule, and
a hot gas supply pipe that extends into said sealed container for introducing hot gas into the container.

4. The apparatus of claim 3, wherein the hot box has a heating jacket.

5. The apparatus of claim 3, wherein the source solution is 1-methyl pyrrolidine alane (MPA).

6. The apparatus of claim 1, wherein the source gas supply pipe has a heating jacket.

7. The apparatus of claim 1, and further comprising a chamber pressure sensor connected to the process chamber so as to sense the pressure in the process chamber.

8. The apparatus of claim 7, wherein the chamber pressure sensor comprises a plurality of baratron sensors.

9. The apparatus of claim 1, and further comprising at least one auxiliary gas pipe extending to the process chamber for connecting a source of inactive gas to the process chamber.

10. The apparatus of claim 1, and further comprising:
a chuck disposed in the process chamber so as to support a wafer in the chamber;
a first auxiliary gas supply pipe extending into the process chamber to a location adjacent an outer peripheral edge of the chuck for supplying inactive gas to said location in the chamber adjacent the chuck;
a second auxiliary gas supply pipe extending into the process chamber to the chuck for supplying inactive gas to the chuck; and
a third auxiliary gas supply pipe extending into the process chamber for supplying inactive gas into the chamber.

11. The apparatus of claim 10, wherein the third auxiliary gas supply pipe is connected to the discharge piping.

12. The apparatus of claim 11, and further comprising a chamber pressure sensor, and a transmission pipe connecting the chamber pressure sensor to the process chamber so that the chamber pressure sensor senses the pressure in the process chamber, and wherein the third auxiliary gas supply pipe is connected to the transmission pipe between the chamber pressure sensor and the process chamber.

13. The apparatus of claim 1, wherein the discharge piping comprises a first discharge pipe extending from said process chamber, a second discharge pipe extending from said first discharge pipe, and a dummy discharge pipe extending from said first discharge pipe to a junction of said first and second discharge pipes so as to be disposed in parallel to said first discharge pipe.

14. The apparatus of claim 13, and further comprising a fore line valve and a vacuum pump disposed along said dummy discharge pipe.

15. The apparatus of claim 14, wherein the vacuum pump disposed along said dummy discharge pipe is a turbo pump.

16. The apparatus of claim 13, and further comprising:
a roughing valve disposed along said first discharge pipe and movable between an open position at which the residual gas can flow through the first discharge pipe and a closed position at which the flow of residual gas is cut off from flowing from the process chamber through the first discharge pipe;
an automatic pressure control valve disposed along said first discharge pipe so as to control the pressure within process chamber when the roughing valve is in the open position thereof; and
a gate valve disposed along said first discharge pipe at a location downstream of a location at which the dummy discharge pipe extends from said first discharge pipe, said gate valve movable between an open position and a closed position at which the first discharge pipe is closed so that the residual gas flows through the dummy discharge pipe.

17. The apparatus of claim 16, wherein the discharge pipe pressure sensor is connected to said discharge piping at a location downstream of the roughing valve and the fore line valve.

18. The apparatus of claim 1, wherein said discharge pipe pressure sensor comprises a thermal-couple gauge.

19. The apparatus of claim 1, wherein the pressure sensor protecting valve is a pneumatic valve actuatable by air pressure.

20. The apparatus of claim 1, wherein the pressure sensor protecting valve and said dump valve are pneumatic valves that are each actuatable by air pressure, and further comprising a pneumatic pressure line connected in common to said sensor protecting valve and said dump valve, whereby said sensor protecting valve and said dump valve are both actuated by a change in air pressure in said pneumatic pressure line.

21. A chemical vapor deposition apparatus, comprising:
a source of source gas for the deposition process;
a process chamber in which a metal thin film is formed on a wafer;
a source gas supply pipe connecting said source of source gas to said process chamber and through which the source gas is supplied into the chamber;
a first pressure sensor connected to said process chamber so as to sense the pressure within the process chamber;
at least one auxiliary gas pipe extending to the process chamber for connecting a source of inactive gas to the process chamber;
discharge piping extending from the chamber;
a vacuum pump connected to the discharge piping to produce a vacuum that discharges residual gas within the chamber through the discharge piping;
a second pressure sensor connected to the discharge piping so as to sense the pressure within the discharge piping;
a dump line extending between and connected to the source gas supply pipe and the discharge piping, and bypassing the process chamber;
a dump valve disposed along the dump line, and movable between positions at which the dump line is open and closed to the source gas supply pipe, respectively; and
a pressure sensor protecting valve interposed between said discharge piping and said pressure sensor, said pressure sensor protecting valve movable between an open position at which fluid flowing through the discharge piping flows into the pressure sensor and a closed position at which fluid flowing through the discharge piping is prevented from flowing to said pressure sensor.
